(19) United States
(12) Patent Application Publication
(10) Pub. No.: US 2008/0259695 A1
(43) Pub. Date: Oct. 23, 2008

(54) Semiconductor Memory Devices Having a Demultiplexer and Related Methods of Testing Such Semiconductor Memory Devices

(75) Inventor: Sung-Bum Cho, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/044,094

(22) Filed: Mar. 7, 2008

(30) Foreign Application Priority Data
Apr. 19, 2007 (KR) 10-2007-0038263

(51) Int. Cl. G11C 7/00; G11C 8/00; G11C 29/00

(52) U.S. Cl. 365/189.05; 365/191; 365/233.1; 365/201

(57) ABSTRACT

A semiconductor memory device includes a memory cell array and a demultiplexer that has a first input port that is configured to receive both an address signal and a data signal and a second input port that is configured to receive a control signal that identifies a type of signal that is input to the first input port. Related methods of testing semiconductor memory devices are also provided.

### CROSS REFERENCE TO RELATED APPLICATION

This application claims priority under 35 U.S.C. §119 from Korean Patent Application No. 10-2007-0038263, filed on Apr. 19, 2007, the contents of which are hereby incorporated by reference in their entirety for all purposes as if fully set forth herein.

### FIELD OF THE INVENTION

The present invention relates to semiconductor memory devices, and more particularly, to the testing of semiconductor memory devices.

### BACKGROUND

In general, a semiconductor memory device such as, for example, a dynamic random access memory (“DRAM”) device, should not include any failed memory cells as such cells may result in errors during read and write operations. However, as the number of memory cells integrated into a single chip increases, the possibility of a failed cell being included on the chip also has increased, in spite of improvements in the device fabrication processes. Thus, tests are typically preformed on semiconductor memory devices to identify failed cells so that they may be, for example, replaced with redundant cells.

The time required to test the memory cells of a semiconductor memory device increases with the degree of integration. In order to reduce the test time, parallel bit test methods have been introduced in which multiple memory cells are simultaneously tested.

These parallel bit test methods may employ, for example, an XOR (exclusive OR) or XNOR (exclusive NOR) logic circuit. In such test methods, the same data may be written to a plurality of memory cells, and then, during or after the read operation, a logical operation is performed using the XOR or XNOR logic circuit. When data of the same logic state is read, the memory cells are considered to have passed the test. In contrast, when data having different logic states is read, the memory cells are considered to have failed test. This parallel technique may significantly reduce the required test time.

The above-described test operation is implemented using a tester. The tester generates control signals including commands, addresses, test data patterns, etc. according to a sequence programmed by an engineer, and applies these control signals to chips under test. For example, to test a semiconductor memory device, test data is written to a memory cell corresponding to a specific address, and then the data stored in the memory cell at that address is read to output DQ data. The tester then compares the DQ data output from the semiconductor memory device to the data that was written to the memory cell to determine if the memory cell passed or failed the test. Through such serial test procedures, the tester may identify the addresses corresponding to failed memory cells. An engineer can then execute a repair procedure with respect to the failed memory cells.

As is well known to those skilled in the art, a tester and a chip are connected to perform the parallel bit test. An interface between the tester and the chip may be provided, for example, by using a probe card or by hard wiring the tester to the chip.

FIGS. 1 and 2 illustrate conventional test methods. FIG. 1 illustrates the testing of one chip using a tester, and FIG. 2 illustrates the simultaneous testing of two chips.

As shown in FIG. 1, various pins of a tester and respective pins or pads VDD, ADDRESS, CLOCK, DC, DQ of the chip under test may be connected with each other through a probe card P/C. The tester has a limited number of pins, which serves to limit the number of semiconductor memory devices that may be tested at once. Thus, a CMT (Chip Merged Test) method has been introduced, which is described with reference to FIG. 2.

As shown in FIG. 2, the CMT method shares a driver channel by a probe card. In particular, with the CMT test method, the address, command and clock pins are shared by, for example, two to four chips. A power (VDD) pin, a DC pin, and an input/output pin DQ is allocated to each chip.

However, the CMT method may have signal integrity problems due to signal reflection, and this may result in drops in yield. Additionally, it may be difficult to apply the method to input/output pins, and it may also cause difficulty with respect to the probe cards as the number of shared pins becomes increased.

### SUMMARY

Pursuant to embodiments of the present invention, semiconductor memory devices are provided that include a memory cell array and a demultiplexer. The demulitplexer has a first input port (e.g., an input/output pad or pin) that is configured to receive both an address signal and a data signal and a second input port that is configured to receive a control signal. The control signal identifies the type of signal (i.e., address signal or data signal) that is input to the first input port. The demultiplexer may be configured to separate the address signal from the data signal and to internally transmit the received address signal from the first input port to an address buffer and the received data signal from the first input port to a data buffer.

In some embodiments, the control signal may comprise a flag signal, and the demultiplexer may be configured to transmit the address signal when the flag signal is in a first state (e.g., activated) and to transmit the data signal when the flag signal is in a second state (e.g., deactivated). In such embodiments, the demultiplexer may include a first logic circuit that is configured to generate a data transmission control signal in response to a test mode signal and the flag signal, a data transmission gate circuit that is configured to transmit the data signal in response to the data transmission control signal and a data latch circuit that is configured to latch the data signal output from the data transmission gate circuit and to transmit the data signal to the data buffer. The demultiplexer may also include a second logic circuit that is configured to generate an address transmission control signal in response to the test mode signal and the flag signal, an address transmission gate circuit that is configured to transmit the address signal in response to the address transmission control signal and an address latch circuit that is configured to latch the address signal output from the address transmission gate circuit and to transmit the address signal to the address buffer.

In other embodiments, the control signal may comprise a first test mode signal and a second test mode signal. In these embodiments, the demultiplexer may be configured to transmit the data signal in response to the first test mode signal and to transmit the address signal in response to the second test mode signal. In some embodiments, the second test mode signal is generated after the first test mode signal, and a write or a read command for a test is generated after the generation of the second test mode signal. In these embodiments, the demultiplexer may include a data transmission gate circuit that is configured to transmit the data signal in response to the first test mode signal and a data latch circuit that is configured to latch the data signal output from the data transmission gate circuit and to transmit the data signal to the data buffer. The demultiplexer may also include an address transmission gate circuit that is configured to transmit the address signal in response to the second test mode signal and an address latch circuit that is configured to latch the address signal output from the address transmission gate circuit and to transmit the address signal to the address buffer.

In still other embodiments, the demultiplexer may be configured to receive and latch the address signal at a first time and to receive the data signal at a second time that is different from the first time. In these embodiments, the demultiplexer may be configured to transmit the data signal to the data buffer at the later one of the first time and the second time and to transmit the latched address signal to the address buffer at the later one of the first time and the second time. In some of these embodiments, the control signal may comprise a first clock signal and a second clock signal, and the first time may be the point in time when the first clock signal is generated after activation of a test mode signal, and the second time may be the point in time when the second clock signal is generated after activation of the test mode signal. In other embodiments, the control signal may comprise a single clock signal, and the first time may be, for example, the time of a rising edge of the first pulse of the clock signal that follows activation of a test mode signal, and the second time may be, for example, the time of the rising edge of the second pulse of the clock signal that follows activation of the test mode signal.

Pursuant to further embodiments of the present invention, methods of testing a semiconductor memory device are provided. Pursuant to these methods, an address signal is input at a first time and a data signal is input at a second time through a common input/output pad during a test mode of the semiconductor memory device. The address signal is transmitted from the common input/output pad to an address buffer. The data signal is transmitted from the common input/output pad to a data buffer.

In still other embodiments of the invention, a semiconductor memory device is provided that includes a demultiplexer for separating and internally transmitting an address signal and a data signal when the address signal and the data signal are input through a common input/output pad. In some of these embodiments, the demultiplexer is configured to transmit the address signal and the data signal at different points of time, depending upon an enable state of an address flag signal giving a notice of address input or of a data flag signal giving a notice of data input. In other of these embodiments, the demultiplexer is configured to transmit the data signal to a data input buffer in response to a first test mode signal for a data input, and to transmit the address signal to an address input buffer in response to a second test mode signal produced after a generation of the first test mode signal. In still further of these embodiments, the demultiplexer is configured to receive and latch the address signal at a first time point and to receive the data signal at a second time point that is later than the first time point. The demultiplexer is further configured to transmit the data signal to a data input buffer, and to transmit the latched address signal to an address input buffer at the second time point.

### BRIEF DESCRIPTION OF THE DRAWINGS

The present invention will be more fully understood from the detailed description below and the accompanying drawings which are given by way of illustration only, and thus are not limiting of the present invention. In the drawings:

FIG. 1 illustrates a test for one chip, using a tester, according to conventional techniques;

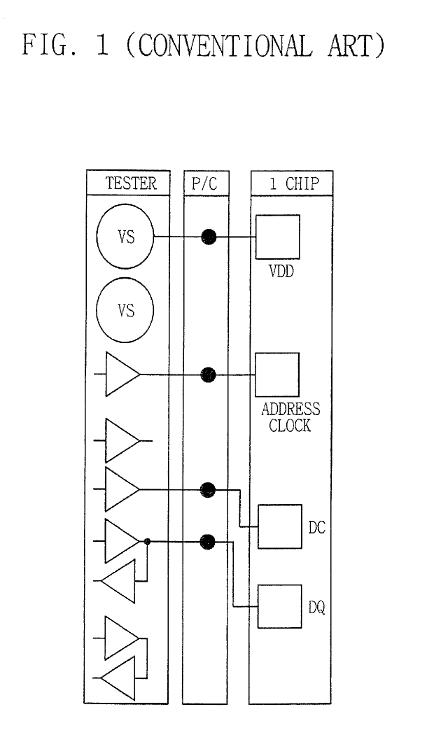

FIG. 2 illustrates a simultaneous test for two chips, using a tester, according to conventional techniques;

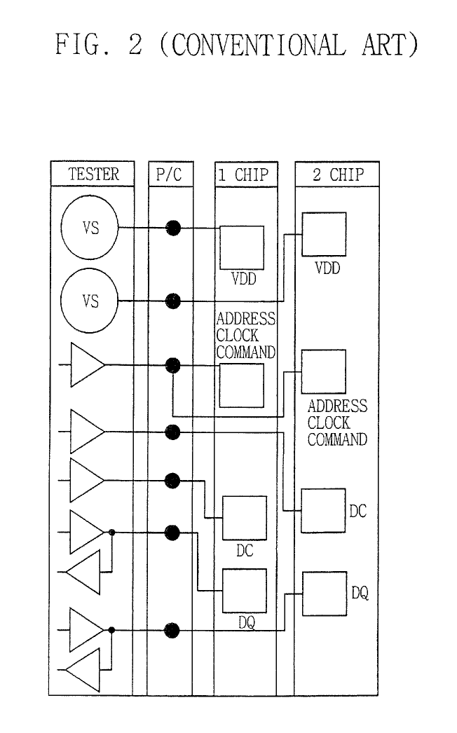

FIG. 3 is a block diagram illustrating a test method of a semiconductor memory device according to some embodiments of the present invention;

FIG. 4 illustrates a first embodiment of the demultiplexer shown in FIG. 3 according to some embodiments of the present invention;

FIG. 5 is a timing diagram illustrating the timing of exemplary operations of the demultiplexer of FIG. 4;

FIG. 6 illustrates a second embodiment of the demultiplexer shown in FIG. 3 according to some embodiments of the present invention;

FIG. 7 is a timing diagram illustrating the timing of exemplary operations of the demultiplexer of FIG. 6;

FIG. 8 illustrates a third embodiment of the demultiplexer shown in FIG. 3 according to some embodiments of the present invention;

FIG. 9 is a timing diagram illustrating the timing of exemplary operations of the demultiplexer of FIG. 8; and

FIG. 10 illustrates an interface circuit of a probe card according to certain embodiments of the present invention.

### DETAILED DESCRIPTION

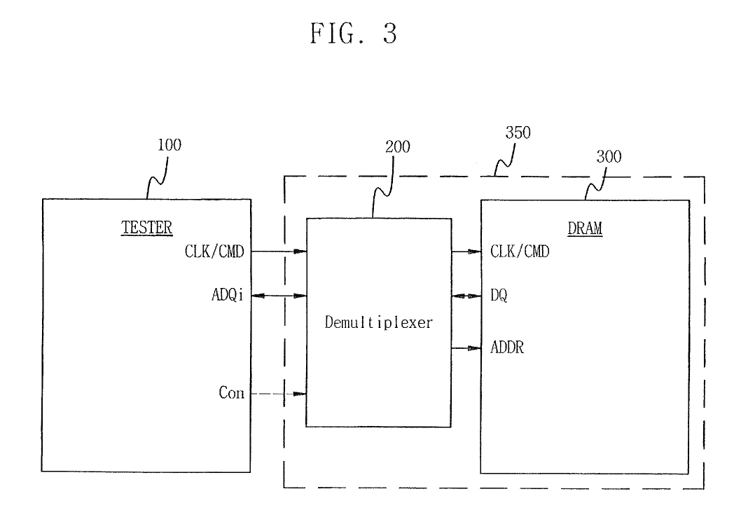

Embodiments of the present invention now will be described more fully hereinafter with reference to FIGS. 3 to 10, in which embodiments of the invention are shown. This invention may, however, be embodied in many different forms and should not be construed as limited to the embodiments set forth herein. Rather these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

FIG. 3 is a block diagram illustrating a test method of a semiconductor memory device 350 according to some embodiments of the present invention. This test method uses a reduced number of test pins. In this test method, the address signals and data signals share an input/output pad

As shown in FIG. 3, the semiconductor memory device 350 according to embodiments of the present invention includes a demultiplexer 200. The remaining components of semiconductor memory device 350 may have the same configuration as a conventional semiconductor memory device.

When an address signal and a data signal are input from the tester 100 through a common input/output pad or pin, the demultiplexer 200 separates and transmits them to an address input buffer or a data input buffer. Thus, the demultiplexer 200 separates the address signal from the data signal when the address signal and the data signal are input from the tester 100 through the same input/output pad ADQi. In general, when the address signal and the data signal are input through the same input/output pad, a collision may occur between these signals. The demultiplexer 200 is configured to resolve and/or prevent such collisions.

It will be appreciated that the demultiplexer 200 may be implemented as part of the semiconductor memory device 300 or as a separate unit. Typically, the demultiplexer 200 will be integrated into the semiconductor memory device 300.

The demultiplexer 200 may use a control signal Con in order to prevent collisions between an input data signal Din and an input address signal Addr. The control signal Con may, for example, be a data flag signal Din Flag, an address flag signal Addr Flag, a plurality of test mode register signals (TMRS), or a test clock signal CLK.

For example, operation using the data flag signal Din Flag or the address flag signal Addr Flag may be performed as follows. A signal ADQi that is input from the tester 100 is divided into an address signal ADDR and a data signal DQ and the signals are transmitted, in response to the data flag signal Din Flag or the address flag signal Addr Flag. The data flag signal Din Flag is generated when a data signal is input from the tester 100, and the address flag signal Addr Flag is generated when address signal is input from the tester 100.

The tester 100 is configured to generate control signals and apply them to tested chips and operate the tested chips by a programming sequence programmed by an engineer, the control signals including a command, an address, a test data pattern, etc.

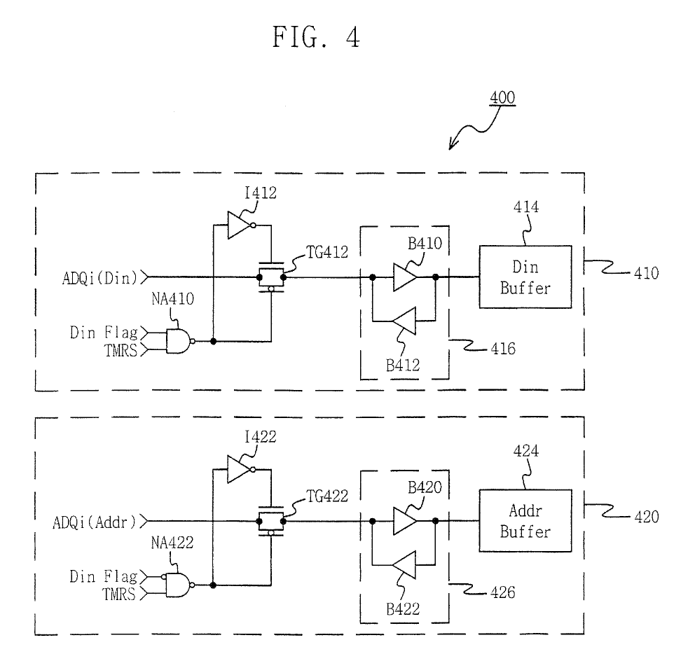

FIG. 4 illustrates a demultiplexer 400 according to certain embodiments of the present invention that may be used, for example as the demultiplexer 200 of FIG. 3. The demultiplexer 400 has different transmission times of address and data signals according to activation of an address flag signal Addr Flag that indicates an address is being input or activation of a data flag signal Din Flag that indicates data is being input. The demultiplexer 400 includes a data input unit 410 and an address input unit 420.

The data input unit 410 identifies and transmits input data signals Din to a data input buffer 414. The data input unit 410 comprises a first logic circuit NA410, a data transmission gate circuit TG412, and a data latch circuit 416.

The first logic circuit NA410 performs a logical operation on a test mode signal (TMRS) and the data flag signal Din Flag, and decides whether or not to transmit data. In particular, if both TMRS and Din are enabled, a data transmission signal is generated. For example, when the test mode signal TMRS and the data flag signal Din FLAG are both at a high level, data Din, which is input through the transmission gate circuit TG412, is transmitted. The first logic circuit NA410 may comprise, for example, a NAND circuit.

The transmission gate circuit TG412 transmits an input data signal Din to data latch circuit 416 in response to a data transmission signal transmitted from the first logic circuit NA410. The data latch circuit 416 latches the data signal Din output from the transmission gate circuit TG412, and transmits it to data input buffer 414. As shown in FIG. 4, the data latch circuit 416 may comprise, for example, two buffer circuits B410 and B412.

The data signal Din that is transmitted to the data input buffer 414 may be written to the general semiconductor memory device 300 (see FIG. 3) as part of a test operation.

The address input unit 420 identifies and transmits input address signals Addr to an address input buffer 424. The address input unit 420 comprises a second logic circuit NA422, an address transmission gate circuit TG422, and an address latch circuit 426.

The second logic circuit NA422 performs a logical operation on the test mode signal TMRS and the data flag signal Din Flag, and decides whether or not to transmit an address signal. For example, if the test mode signal TMRS is enabled and the data flag signal Din Flag is disabled, the address transmission signal is generated. The second logic circuit NA422 may comprise, for example, a NAND circuit.

The address transmission gate circuit TG422 transmits the address signal Addr in response to the address transmission signal transmitted from the second logic circuit NA422. For example, when the address transmission signal has a low level, the address signal Addr is transmitted through the address transmission gate TG422. The address latch circuit 426 latches the address signal Addr output from the address transmission gate circuit TG422, and transmits it to the address input buffer 424. As shown in FIG. 4, the address latch circuit 426 may comprise, for example, two buffer circuits B420 and B422. The address signal Addr that is transmitted to the address input buffer 424 may be used for a read/write operation during a test of the general semiconductor memory device 300 (see FIG. 3).

FIG. 4 illustrates a demultiplexer for demultiplexing address signal Addr and data signal Din in response to data flag signal Din Flag that gives data input information in a test operating mode. It will be appreciated in light of the present disclosure, however, that a demultiplexer which demultiplexes address signals Addr and data signals Din in response to an address flag signal Addr Flag that gives address input information may be used instead. That is, in the circuit of FIG. 4, address flag signal Addr Flag may be input instead of data flag signal Din Flag. Further, first logic circuit NA410 of the data input unit 410 may be replaced with a logic circuit that has the same structure as second logic circuit NA422 of the address input unit 420, and the second logic circuit NA422 of the address input unit 420 may be replaced with a logic circuit that has the same structure as the first logic circuit NA410 of the data input unit 410. As the implementation of this embodiment is apparent to those skilled in the art in light of the detailed description of the data flag embodiment, a detailed description of this embodiment is omitted.

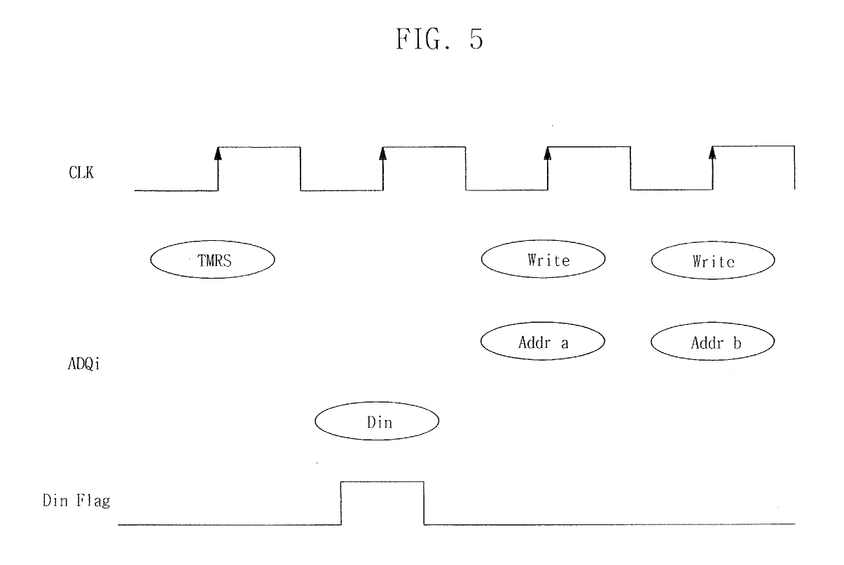

FIG. 5 is a timing diagram illustrating the timing of exemplary operations of the demultiplexer 400 of FIG. 4.

As shown in FIG. 5, the test mode signal TMRS is generated at a rising edge of test clock signal CLK. This initiates the test mode. A data signal Din is input from the tester 100 through the data and address signal input/output pin ADQi. As a data signal is being input, the data flag signal Din Flag is activated. As the data flag signal Din Flag is activated, the data input unit 410 transmits the data signal Din to the data input buffer 410. As is also shown in FIG. 5, subsequently, a command such as a write command Write etc. is produced, and a first address Addr a is applied. At this time, the data flag signal Din has been disabled. As such, the first address signal Addr a is input through the address input unit 420 and, as such, it will not collide with any data Din. This is also the case with respect to a second address signal Addr b that is generated later.

As described above, operation of the demultiplexer 400 is controlled by the activation state of either a data flag signal Din Flag or an address flag signal Addr Flag in the test operating mode and, as such, collisions between data signals and address signals that are input through a shared input/output pad or pin can be prevented.

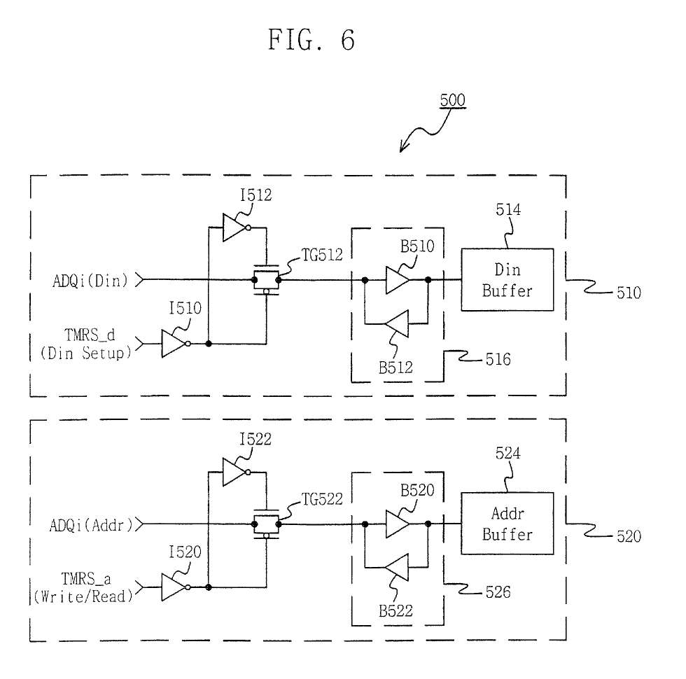

FIG. 6 illustrates a demultiplexer 500 according to further embodiments of the present invention that may be used, for example as the demultiplexer 200 of FIG. 3.

As shown in FIG. 6, the demultiplexer 500 transmits a data signal Din that is output from an input/output pin ADQi of tester 100 to data input buffer 514, in response to a first test mode signal TMRS_d. The demultiplexer 500 also transmits the address signal Addr to address input buffer 524 in response to a second test mode signal TMRS_a that is generated after generation of the first test mode signal TMRS_d. This serves to prevent collisions between the address signal Addr and the data signal Din.

The demultiplexer 500 includes a data input unit 510 and an address input unit 520. The data input unit 510 separates and transmits input data signals Din to data input buffer 514, and comprises inverters I510 and I512, a data transmission gate circuit TG512, and a data latch circuit 516.

The data input unit 510 operates when the first test mode signal TMRS_d is enabled or generated. After the first test mode signal TMRS_d is generated, an input data signal Din is transmitted to the data input buffer 514. The transmission gate circuit TG512 operates in response to the first test mode signal TMRS_d, and an input data signal Din is transmitted to data latch circuit 516. The data latch circuit 516 latches the data signal Din output from the transmission gate circuit TG512, and transmits it to data input buffer 514. The data latch circuit 516 may comprise, for example, two buffer circuits B510 and B512.

The data signal Din that is transmitted to the data input buffer 514 may be used, for example, for a write operation performed during a test of the semiconductor memory device 300.

The address input unit 520 separates and transmits input address signals Addr to address input buffer 524. The address input unit 520 includes inverters I520 and I522, an address transmission gate circuit TG522, and an address latch circuit 526.

The address input unit 520 operates when the second test mode signal TMRS_a is enabled or generated. That is, the second test mode signal TMRS_a is generated, and at this time, an input data signal Addr is transmitted to the address input buffer 524. The address transmission gate circuit TG522 transmits the address signal Addr that is input when the second test mode signal TMRS_a is generated. The address latch circuit 526 latches the address signal Addr output from the address transmission gate circuit TG522, and transmits it to the address input buffer 524. The address latch circuit 526 may comprise two buffer circuits B520 and B522.

When a write command Write is input, a read/write operation for a test may be performed through a previously input data signal Din and a later input address signal Addr as may be done in a general semiconductor memory device.

While the test operating mode of FIG. 6 has been described above such that the second test mode signal TMRS_a is generated after the first test mode signal TMRS_d, it will be appreciated that the generation sequence of the first test mode signal TMRS_d and the second test mode signal TMRS_a may be varied. For example, the second test mode signal TMRS_a may be generated first, followed by the first test mode signal TMRS_d. In this case, address signal Addr may be input prior to data signal Din.

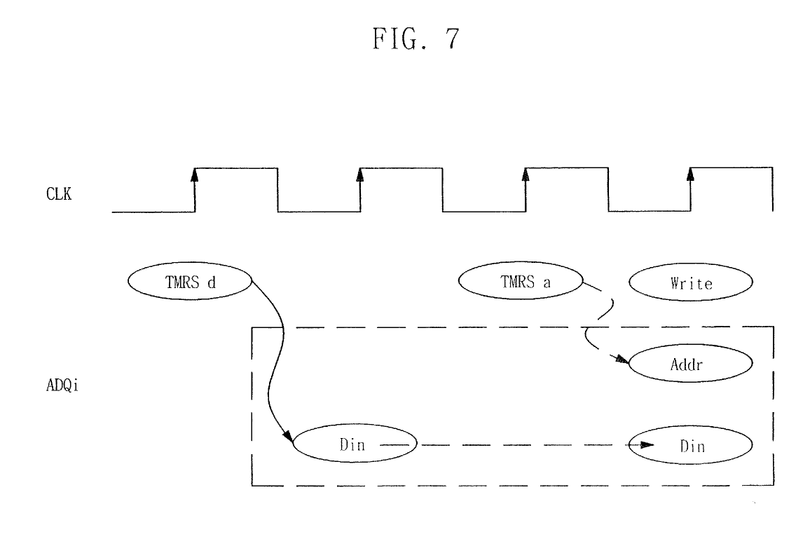

FIG. 7 is a timing diagram illustrating the timing of exemplary operations of the demultiplexer of FIG. 6.

As shown in FIG. 7, the first test mode signal TMRS_d is produced at a rising edge time of the test clock signal CLK. Then, a test mode starts. In response to generation of the first test mode signal TMRS_d, data signal Din is input through data and address signal input/output pin ADQi. Then, a second test mode signal TMRS_a is generated. Subsequently, a command such as a write command Write, etc., is produced and an address signal Addr is applied and transmitted to the address buffer. The Write operation is then performed in response to the write command Write.

As described above, the demultiplexer 500 is controlled via the test mode signals TMRS-d and TMRS_a so that collisions between data signals and address signals input through a common input/output pad or pin can be reduced and/or prevented.

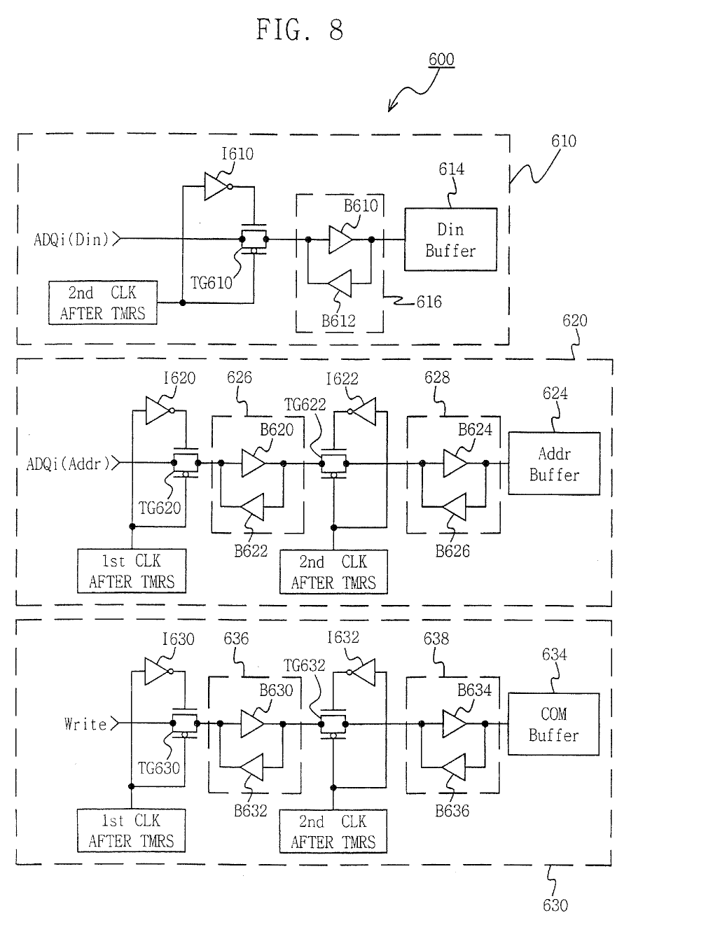

FIG. 8 illustrates a demultiplexer 600 according to further embodiments of the present invention that may be used, for example, as the demultiplexer 200 of FIG. 3.

The demultiplexer 600 receives and latches an address signal Addr at a first time point, and receives the data signal Din at a second time point that is later in time than the first time point to transmit the data signal to data input buffer 614, and transmits the latched address signal Addr to address input buffer 624 at the second time point.

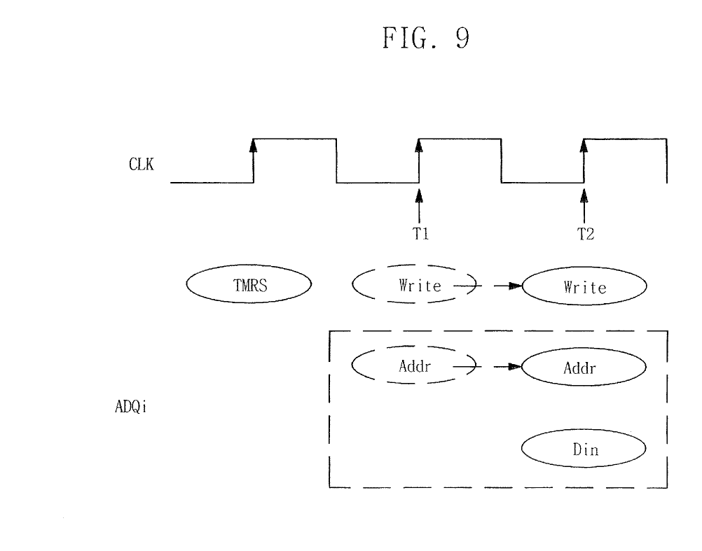

As shown in FIG. 8, the first time point may be, for example, the time at which a first clock signal 1^{st} CLK is generated after a generation of the test mode signal TMRS. The second time point may be, for example, the time when a second clock signal 2^{nd} CLK is generated after the generation of the test mode signal TMRS. As another example, the first time point may be the rising edge of the first pulse of a test clock signal CLK that follows generation of the test mode signal, and the second time point may be the rising edge of the next (i.e., second) pulse of the test clock signal CLK. These first and second pulses of the test clock signal CLK are shown in FIG. 9 as ‘T1’ and ‘T2’.

Assuming that the generated time of the first clock signal 1st CLK and the rising edge of the first pulse of the test clock signal CLK are coincident, and that the generated time of the second clock signal 2^{nd} CLK and the rising edge of the second pulse of the test clock signal CLK are coincident, the following description is provided.

The demultiplexer 600 comprises a data input unit 610, an address input unit 620 and a command input unit 630.

The data input unit 610 receives the data signal Din at a second time point that is later than a first time point, and transmits the received data signal Din to data input buffer 614. The data input unit 610 further includes a data transmission gate circuit TG610 and a data latch circuit 616.

The transmission gate circuit TG610 operates at the second time point, and transmits the input data signal Din to the data latch circuit 616. The data latch circuit 616 latches the data signal Din output from the transmission gate circuit TG610, and transmits it to the data input buffer 614. The data latch circuit 616 may comprise, for example, two buffer circuits B610 and B612. The data signal Din transmitted to the data input buffer 614 may be used, for example, for a write operation during a test of the semiconductor memory device.

The address input unit 620 receives and latches the address signal Addr at the first time point, and transmits it to the address buffer 624 at the second time point. The address input unit 620 includes first and second transmission gate circuits TG620 and TG622, and first and second address latches 626 and 628.

The first transmission gate circuit TG620 transmits address signal Addr that is input at the first time point to the first latch circuit 626. The first latch circuit 626 latches the address signal Addr output from the first transmission gate circuit TG620. The first latch circuit 626 may comprise, for example, two buffer circuits B620 and B622. The second transmission gate circuit TG622 operates at the second time point, and transmits the address signal Addr that is input from the first latch circuit 626 to the second latch circuit 628. The second latch circuit 628 latches the address signal Addr that is output from the second transmission gate circuit TG622, and transmits it to address input buffer 624. The address latch circuit 628 may comprise, for example, two input buffer circuits B624 and B626.

The command input unit 630 has the same configuration as the address input unit 620, except that it is configured to input the command signal Write instead of the address signal Addr and to transmit this command signal Write to a command buffer 634.

The command input unit 630 is configured with an assumption that the command signal is input at the same time point as the address signal Addr. But, when the command signal Write is input at the second time point, the command input unit 630 is not needed or may have the same configuration as the data input unit 610.

FIG. 9 is a timing diagram illustrating the timing of exemplary operations of the demultiplexer of FIG. 8.

As shown in FIG. 9, the test mode signal TMRS is generated at a rising edge of test clock signal CLK in order to initiate the test mode. Then, write command Write and address signal Addr are input at the first time point T1. The address signal Addr is latched until second time point T2 through the address input unit 620, and the command signal Write is also latched until the second time point T2. Subsequently, when data signal Din is input at the second time point T2, a general write operation for a test is performed.

As described above, the demultiplexer 600 is configured to use the test clock signal CLK in a test operating mode to prevent collisions between data signals and address signals input through a common input/output pad or pin.

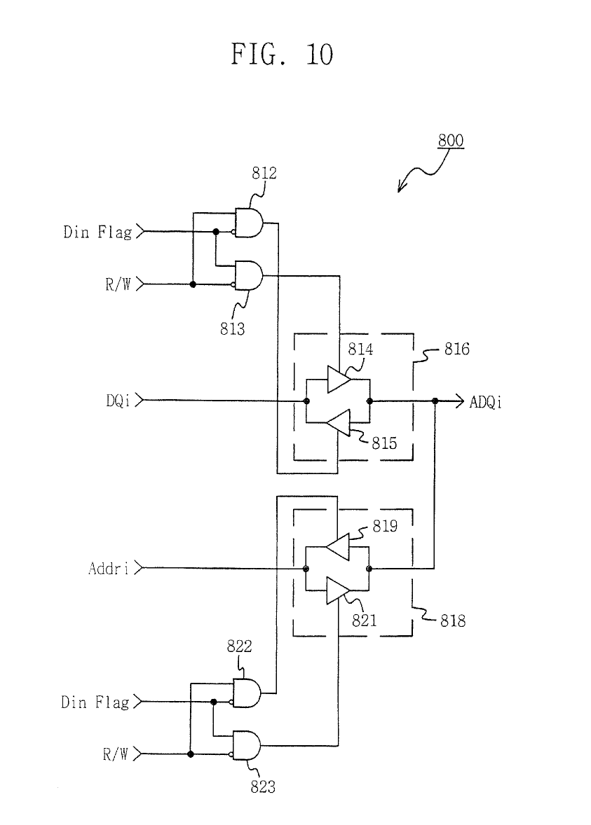

FIG. 10 illustrates another embodiment of the present invention in which a multiplexer circuit of a probe card operates as an interface between a semiconductor memory device and a tester. The interface circuit 800 of FIG. 10 thus may be used to multiplex address pin Addri and data input/output pin DQi of the tester.

As shown in FIG. 10, the interface circuit 800 may comprise AND circuits 812, 813, 822 and 823, and latch circuits 816 and 818 constructed of buffers 814, 815, 819, 821, with a wiring structure as shown in FIG. 10, to receive a data flag signal Din Flag, commands R/W, address Addr, and data.

The interface circuit 800 can be used, for example, when the tester does not have a direct hard wiring with the semiconductor memory device.

Although only a case of test operation is described above in the embodiments of the invention, the invention may be equally employed to a normal operation, or with some application.

As described above, according to some embodiments of the invention, the number of test pins can be reduced by transmitting data and address through one input/output pad, thereby providing a simultaneous test for a large number of semiconductor memory devices. In addition, productivity can increase and test cost can be reduced, substantially reducing a collision between address signal and data signal and improving test efficiency.

It will be apparent to those skilled in the art that modifications and variations can be made in the present invention without deviating from the spirit or scope of the invention. Thus, it is intended that the present invention cover any such modifications and variations of this invention provided they come within the scope of the appended claims and their equivalents. Accordingly, such changes and modifications are seen to be within the true spirit and scope of the invention as defined by the appended claims. It will also be appreciated that the drawings and specification merely disclose typical embodiments of the invention and, although specific terms are employed, they are used in a generic and descriptive sense only and not for purposes of limitation.

What is claimed is:

1. A semiconductor memory device, comprising:
a memory cell array; and
a demultiplexer that includes a first input port that is configured to receive both an address signal and a data signal and a second input port that is configured to receive a control signal that identifies a type of signal that is input to the first input port.

2. The semiconductor memory device of claim 1, wherein the demultiplexer is configured to separate the address signal from the data signal and to internally transmit the received address signal and the received data signal within the demultiplexer.

3. The semiconductor memory device of claim 2, wherein the demultiplexer internally transmits the received data signal from the first input port to a data buffer and internally transmits the received address signal from the first input port to an address buffer.

4. The semiconductor memory device of claim 2, wherein the control signal comprises a flag signal, and wherein the demultiplexer is configured to transmit the address signal when the flag signal is in a first state and to transmit the data signal when the flag signal is in a second state.

5. The semiconductor memory device of claim 4, wherein the flag signal comprises an address flag signal that indicates that an address is being input through the first input port or a data flag signal that indicates that data is being input through the first input port.

6. The semiconductor memory device of claim 4, wherein the demultiplexer comprises:
a first logic circuit that is configured to generate a data transmission control signal in response to a test mode signal and the flag signal;
a data transmission gate circuit that is configured to transmit the data signal in response to the data transmission control signal;
a data latch circuit that is configured to latch the data signal output from the data transmission gate circuit and to transmit the data signal to the data buffer;
a second logic circuit that is configured to generate an address transmission control signal in response to the test mode signal and the flag signal;
an address transmission gate circuit that is configured to transmit the address signal in response to the address transmission control signal; and
an address latch circuit that is configured to latch the address signal output from the address transmission gate circuit and to transmit the address signal to the address buffer.

7. The semiconductor memory device of claim 6, wherein the first and second logic circuits comprise NAND circuits.

8. The semiconductor memory device of claim 3, wherein the control signal comprises a first test mode signal and a second test mode signal, and wherein the demultiplexer is configured to transmit the data signal in response to the first test mode signal and to transmit the address signal in response to the second test mode signal.

9. The semiconductor memory device of claim 8, wherein the second test mode signal is generated after the first test mode signal.

10. The semiconductor memory device of claim 9, wherein a write or a read command for a test is generated after the generation of the second test mode signal.

11. The semiconductor memory device of claim 8, wherein the demultiplexer comprises:
a data transmission gate circuit that is configured to transmit the data signal in response to the first test mode signal;
a data latch circuit that is configured to latch the data signal output from the data transmission gate circuit and to transmit the data signal to the data buffer;
an address transmission gate circuit that is configured to transmit the address signal in response to the second test mode signal; and
an address latch circuit that is configured to latch the address signal output from the address transmission gate circuit and to transmit the address signal to the address buffer.

12. The semiconductor memory device of claim 3, wherein the demultiplexer is configured to receive and latch the address signal at a first time and to receive the data signal at a second time that is different from the first time.

13. The semiconductor memory device of claim 12, wherein the demultiplexer is configured to transmit the data signal to the data buffer at the later one of the first time and the second time and to transmit the latched address signal to the address buffer at the later one of the first time and the second time.

14. The semiconductor memory device of claim 13, wherein the control signal comprises a first clock signal and a second clock signal, and wherein the first time is a point in time when the first clock signal is generated after activation of a test mode signal, and the second time is a point in time when the second clock signal is generated after activation of the test mode signal.

15. The semiconductor memory device of claim 13, wherein the control signal comprises a clock signal, and wherein the first time is the time of a rising edge of a pulse of the clock signal that follows activation of a test mode signal, and the second time is the time of a rising edge of another pulse of the clock signal that follows activation of the test mode signal.

16. The semiconductor memory device of claim 13, wherein the demultiplexer comprises:
a first address transmission gate circuit that is configured to transmit the address signal at the first time;
a first address latch circuit that is configured to latch the address signal output from the first address transmission gate circuit;
a second address transmission gate circuit that is configured to receive the address signal from the first address latch circuit and to transmit the received address signal at the second time; and
a second address latch circuit that is configured to latch the address signal output from the second address transmission gate circuit and to transmit the address signal to the address buffer.

17. The semiconductor memory device of claim 16, wherein the demultiplexer further comprises:
a data transmission gate circuit that is configured to transmit the data signal at the second time; and
a data latch circuit that is configured to latch the data signal output from the data transmission gate circuit and to transmit the data signal to the data buffer;

18. A method of testing a semiconductor memory device, the method comprising:
inputting an address signal at a first time and a data signal at a second time through a common input/output pad during a test mode of the semiconductor memory device;
transmitting the address signal from the common input/output pad to an address buffer; and
transmitting the data signal from the common input/output pad to a data buffer.

19. The method of claim 18, wherein the address signal is transmitted when a flag signal is in a first state and wherein the data signal is transmitted when the flag signal is in a second state.

20. The method of claim 18, wherein the address signal is transmitted in response to a first test mode signal and wherein the data signal is transmitted in response to a second test mode signal.

21. The method of claim 18, the method further comprising latching the input address signal at a first time following activation of a test mode signal, wherein the data signal is input at a second time that is later than the first time, and wherein the latched address signal is transmitted to the address buffer at the second time.

22. The method of claim 21, wherein the first time is a point in time when a first clock signal is generated after activation of the test mode signal, and the second time is a point in time when a second clock signal is generated after activation of the test mode signal.

23. The method of claim 21, wherein the first time is a time of a rising edge of a first pulse of a test clock signal that follows activation of the test mode signal, and the second time is a rising edge of another pulse of the test clock signal that follows activation of the test mode signal.
